(19) United States
(12) Patent Application Publication
(10) Pub. No.: US 2026/0266878 A1
(43) Pub. Date: Sep. 10, 2026

(54) VOLTAGE MONITORING CIRCUIT AND POWER SUPPLY CIRCUIT

(71) Applicant: ROHM CO., LTD., Kyoto (JP)

(72) Inventor: Haruka KAKIMOTO, Kyoto (JP)

(21) Appl. No.: 19/556,283

(22) Filed: Mar. 4, 2026

(30) Foreign Application Priority Data
Mar. 7, 2025 (JP) 2025-036289

(51) Int. Cl. G01R 19/165

(52) U.S. Cl. CPC G01R 19/16519

(57) ABSTRACT

A voltage monitoring circuit includes: a first field-effect transistor configured to be fed at its gate with a first reference voltage; a second field-effect transistor configured to be fed at its gate with a second reference voltage higher than the first reference voltage; a third field-effect transistor configured to be fed at its gate with a monitoring target voltage and to have its source connected to the source of the first field-effect transistor and to the source of the second field-effect transistor; a fourth field-effect transistor configured to be turned on and off according to the drain current of the second field-effect transistor; and a fifth field-effect transistor configured to be turned on and off according to the drain current of the first field-effect transistor.

### CROSS-REFERENCE TO RELATED APPLICATIONS

This nonprovisional application claims priority under 35 U.S.C. § 119(a) on Patent Application No. 2025-036289 filed in Japan on Mar. 7, 2025, the entire contents of which are hereby incorporated by reference.

### BACKGROUND OF THE INVENTION

### 1. Technical Field

The present disclosure relates to voltage monitoring circuits and power supply circuits.

### 2. Description of Related Art

A window comparator is a voltage monitoring circuit configured to monitor whether a monitoring target voltage is within a predetermined range (a range higher than a first reference voltage but lower than a second reference voltage).

A known window comparator is configured with two comparators and one OR circuit (see, for example, JP-A-2016-75252, paragraphs 0067 and 0068).

### BRIEF DESCRIPTION OF THE DRAWINGS

FIG. 1 is a diagram showing the configuration of a power monitoring circuit according to a first embodiment.

FIG. 2 is a diagram showing the waveforms of an input voltage and an output voltage in the power monitoring circuit according to the first embodiment.

FIG. 3 is a diagram showing the configuration of a power monitoring circuit according to a second embodiment.

FIG. 4 is a diagram showing the waveforms of an input voltage and an output voltage in the power monitoring circuit according to the second embodiment.

FIG. 5 is a diagram showing the configuration of a power monitoring circuit according to a third embodiment.

FIG. 6 is a diagram showing the waveforms of an input voltage and an output voltage in the power monitoring circuit according to the third embodiment.

FIG. 7 is a diagram showing the configuration of a power monitoring circuit according to a fourth embodiment.

FIG. 8 is a diagram showing the waveforms of an input voltage and an output voltage in the power monitoring circuit according to the fourth embodiment.

FIG. 9 is a diagram showing the configuration of a power monitoring circuit according to a fifth embodiment.

FIG. 10 is a diagram showing the waveforms of an input voltage and an output voltage in the power monitoring circuit according to the fifth embodiment.

FIG. 11 is a diagram showing the configuration of a power monitoring circuit according to a sixth embodiment.

FIG. 12 is a diagram showing the waveforms of an input voltage and an output voltage in the power monitoring circuit according to the sixth embodiment.

FIG. 13 is a diagram showing the configuration of a power monitoring circuit according to a seventh embodiment.

FIG. 14 is a diagram showing the waveforms of an input voltage and an output voltage in the power monitoring circuit according to the seventh embodiment.

FIG. 15 is a diagram showing the configuration of a power monitoring circuit according to an eighth embodiment.

FIG. 16 is a diagram showing the waveforms of an input voltage and an output voltage in the power monitoring circuit according to the eighth embodiment.

FIG. 17 is a diagram showing an outline of the configuration of a power supply circuit.

### DETAILED DESCRIPTION OF PREFERRED EMBODIMENTS

In the present specification, a MOSFET (metal-oxide-semiconductor field-effect transistor) denotes a field-effect transistor with a gate structure composed of at least three layers, namely a “layer of a conductor or of a semiconductor with a low resistance such as polysilicon,” an “insulating layer,” and a “semiconductor layer of a P type, an N type, or an intrinsic type.” That is, the gate structure of a MOSFET is not limited to a three-layer structure of a metal, an oxide, and a semiconductor. In the following description, a P-channel MOSFET is referred to as a PMOS transistor and an N-channel MOSFET is referred to as an NMOS transistor.

### First Embodiment

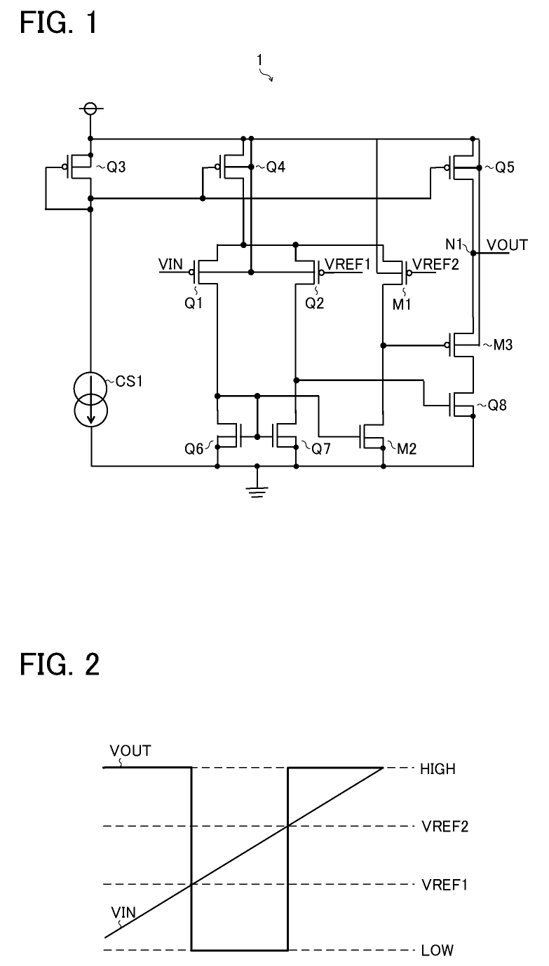

FIG. 1 is a diagram showing the configuration of a power monitoring circuit 1 according to a first embodiment. The power monitoring circuit 1 includes a comparator, a PMOS transistor M1, an NMOS transistor M2, and a PMOS transistor M3.

The comparator in the power monitoring circuit 1 includes an input differential pair comprising PMOS transistors Q1 and Q2, a first current mirror circuit comprising PMOS transistors Q3 to Q5, a current source CS1, and a second current mirror circuit comprising NMOS transistors Q6 and Q7.

A supply voltage is applied to the sources of the PMOS transistors Q3 to Q5 and to the back gates of the PMOS transistors Q1 to Q5, M1, and M3. The gates of the PMOS transistors Q3 to Q5 and the drain of the PMOS transistor Q3 are connected to the first terminal of the current source CS1.

The drain of the PMOS transistor Q4 is connected to the sources of the PMOS transistors Q1, Q2, and M1.

An input voltage VIN is applied to the gate of the PMOS transistor Q1. A first reference voltage VREF1 is applied to the gate of the PMOS transistor Q2. A second reference voltage VREF2 is applied to the gate of the PMOS transistor M1.

The drain of the PMOS transistor Q1 is connected to the drain of the NMOS transistor Q6 and to the gates of the NMOS transistors Q6, Q7, and M2. The drain of the PMOS transistor Q2 is connected to the drain of the NMOS transistor Q7 and to the gate of an NMOS transistor Q8. The drain of the PMOS transistor M1 is connected to the drain of the NMOS transistor M2 and to the gate of the PMOS transistor M3.

The drain of the PMOS transistor Q5 is connected to the source of the PMOS transistor M3. From a connection node N1 between the drain of the PMOS transistor Q5 and the source of the PMOS transistor M3, an output voltage VOUT is output.

The drain of the PMOS transistor M3 is connected to the drain of the NMOS transistor Q8.

A ground voltage is applied to the second terminal of the current source CS1 and to the sources and back gates of the NMOS transistors Q6 to Q8 and M2.

Configured as described above, the power monitoring circuit 1 operates as follows.

If the input voltage VIN is lower than the first reference voltage VREF1, the drain current of the PMOS transistor Q2 and the drain current of the PMOS transistor M1 are each lower than the drain current of the PMOS transistor Q1. Thus, the gate voltage of the NMOS transistor Q8 is at low level, so that the NMOS transistor Q8 is in off state, and the gate voltage of the PMOS transistor M3 is at low level, so that the PMOS transistor M3 is in on state. As a result, the output voltage VOUT is at high level.

If the input voltage VIN is higher than the first reference voltage VREF1 but lower than the second reference voltage VREF2, the drain current of the PMOS transistor Q1 and the drain current of the PMOS transistor Q2 are each higher than the drain current of the PMOS transistor M1. Thus, the gate voltage of the NMOS transistor Q8 is at high level, so that the NMOS transistor Q8 is in on state, and the gate voltage of the PMOS transistor M3 is at low level, so that the PMOS transistor M3 is in on state. As a result, the output voltage VOUT is at low level.

If the input voltage VIN is higher than the second reference voltage VREF2, the drain current of the PMOS transistor Q2 and the drain current of the PMOS transistor M1 are each higher than the drain current of the PMOS transistor Q1. Thus, the gate voltage of the NMOS transistor Q8 is at high level, so that the NMOS transistor Q8 is in on state, and the gate voltage of the PMOS transistor M3 is at high level, so that the PMOS transistor M3 is in off state. As a result, the output voltage VOUT is at high level.

Thus, the power monitoring circuit 1 is configured to monitor whether the input voltage VIN as a monitoring target voltage is within a predetermined range (the range higher than the first reference voltage VREF1 but lower than the second reference voltage VREF2). As shown in FIG. 2, the power monitoring circuit 1 is configured to output, if the input voltage VIN is in the predetermined range, a low-level output voltage VOUT and, if the input voltage VIN is out of the predetermined range, a high-level output voltage VOUT.

The power monitoring circuit 1 is configured not to require two comparators, and this helps reduce the circuit scale. The logic levels of the output voltage VOUT can be reversed by additionally providing the power monitoring circuit 1 with an inverter of which the input terminal is connected to the connection node N1 and using the voltage output from the output terminal of the inverter as the output voltage VOUT.

### Second Embodiment

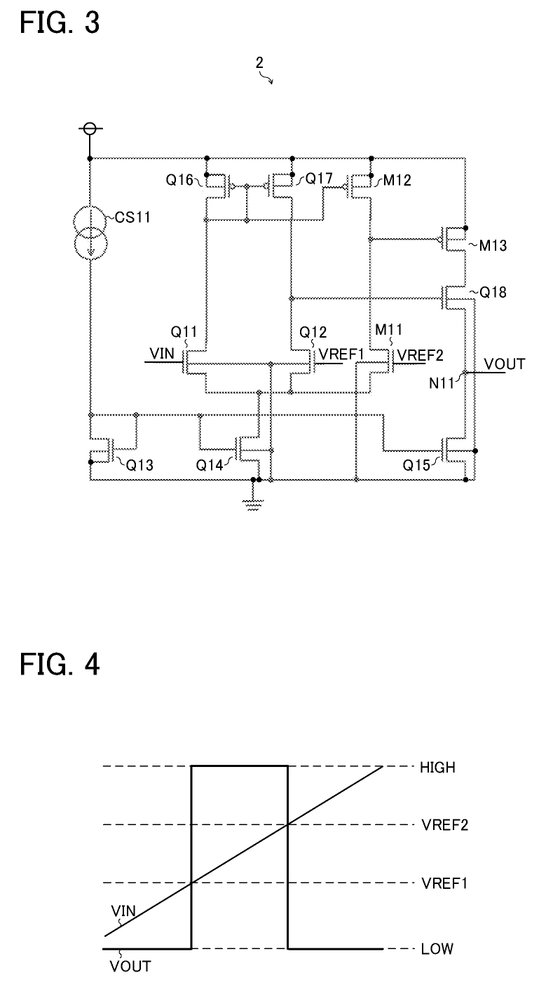

FIG. 3 is a diagram showing the configuration of a power monitoring circuit 2 according to a second embodiment. The power monitoring circuit 2 includes a comparator, an NMOS transistor M11, a PMOS transistor M12, and a PMOS transistor M13.

The comparator in the power monitoring circuit 2 includes an input differential pair comprising NMOS transistors Q11 and Q12, a first current mirror circuit comprising NMOS transistors Q13 to Q15, a current source CS11, and a second current mirror circuit comprising PMOS transistors Q16 and Q17.

A ground voltage is applied to the sources of the NMOS transistors Q13 to Q15 and to the back gates of the NMOS transistors Q11 to Q15, M11, and Q18. The gates of the NMOS transistors Q13 to Q15 and the drain of the NMOS transistor Q13 are connected to the first terminal of the current source CS11.

The drain of the NMOS transistor Q14 is connected to the sources of the NMOS transistors Q11, Q12, and M11.

An input voltage VIN is applied to the gate of the NMOS transistor Q11. A first reference voltage VREF1 applied to the gate of the NMOS transistor Q12. A second reference voltage VREF2 is applied to the gate of the NMOS transistor M11.

The drain of the NMOS transistor Q11 is connected to the drain of the PMOS transistor Q16 and to the gates of the PMOS transistors Q16, Q17, and M12. The drain of the NMOS transistor Q12 is connected to the drain of the PMOS transistor Q17 and to the gate of a NMOS transistor Q18. The drain of the NMOS transistor M11 is connected to the drain of the PMOS transistor M12 and to the gate of the PMOS transistor M13.

The drain of the NMOS transistor Q15 is connected to the source of the NMOS transistor Q18. From the connection node N11 between the drain of the NMOS transistor Q15 and the source of the NMOS transistor Q18, an output voltage VOUT is output.

The drain of the NMOS transistor Q18 is connected to the drain of the PMOS transistor M13.

A supply voltage is applied to the second terminal of the current source CS11 and to the sources and back gates of the PMOS transistors Q16, Q17, M12, and M13.

Configured as described above, the power monitoring circuit 2 operates as follows.

If the input voltage VIN is lower than the first reference voltage VREF1, the drain current of the NMOS transistor Q12 and the drain current of the NMOS transistor M11 are each higher than the drain current of the NMOS transistor Q11. Thus, the gate voltage of the NMOS transistor Q18 is at low level, so that the NMOS transistor Q18 is in off state, and the gate voltage of the PMOS transistor M13 is at low level, so that the PMOS transistor M13 is in on state. As a result, the output voltage VOUT is at low level.

If the input voltage VIN is higher than the first reference voltage VREF1 but lower than the second reference voltage VREF2, the drain current of the NMOS transistor Q11 and the drain current of the NMOS transistor Q12 are each lower than the drain current of the NMOS transistor M11. Thus, the gate voltage of the NMOS transistor Q18 is at high level, so that the NMOS transistor Q18 is in on state, and the gate voltage of the PMOS transistor M13 is at low level, so that the PMOS transistor M13 is in on state. As a result, the output voltage VOUT is at high level.

If the input voltage VIN is higher than the second reference voltage VREF2, the drain current of the NMOS transistor Q12 and the drain current of the NMOS transistor M11 are each lower than the drain current of the NMOS transistor Q11. Thus, the gate voltage of the NMOS transistor Q18 is at high level, so that the NMOS transistor Q18 is in on state, and the gate voltage of the PMOS transistor M13 is at high level, so that the PMOS transistor M13 is in off state. As a result, the output voltage VOUT is at low level.

Thus, the power monitoring circuit 2 is configured to monitor whether the input voltage VIN as a monitoring target voltage is within a predetermined range (the range higher than the first reference voltage VREF1 but lower than the second reference voltage VREF2). As shown in FIG. 4, the power monitoring circuit 2 is configured to output, if the input voltage VIN is in the predetermined range, a high-level output voltage VOUT and, if the input voltage VIN is out of the predetermined range, a low-level output voltage VOUT.

The power monitoring circuit 2 is configured not to require two comparators, and this helps reduce the circuit scale. The logic levels of the output voltage VOUT can be reversed by additionally providing the power monitoring circuit 2 with an inverter of which the input terminal is connected to the connection node N11 and using the voltage output from the output terminal of the inverter as the output voltage VOUT.

### Third Embodiment

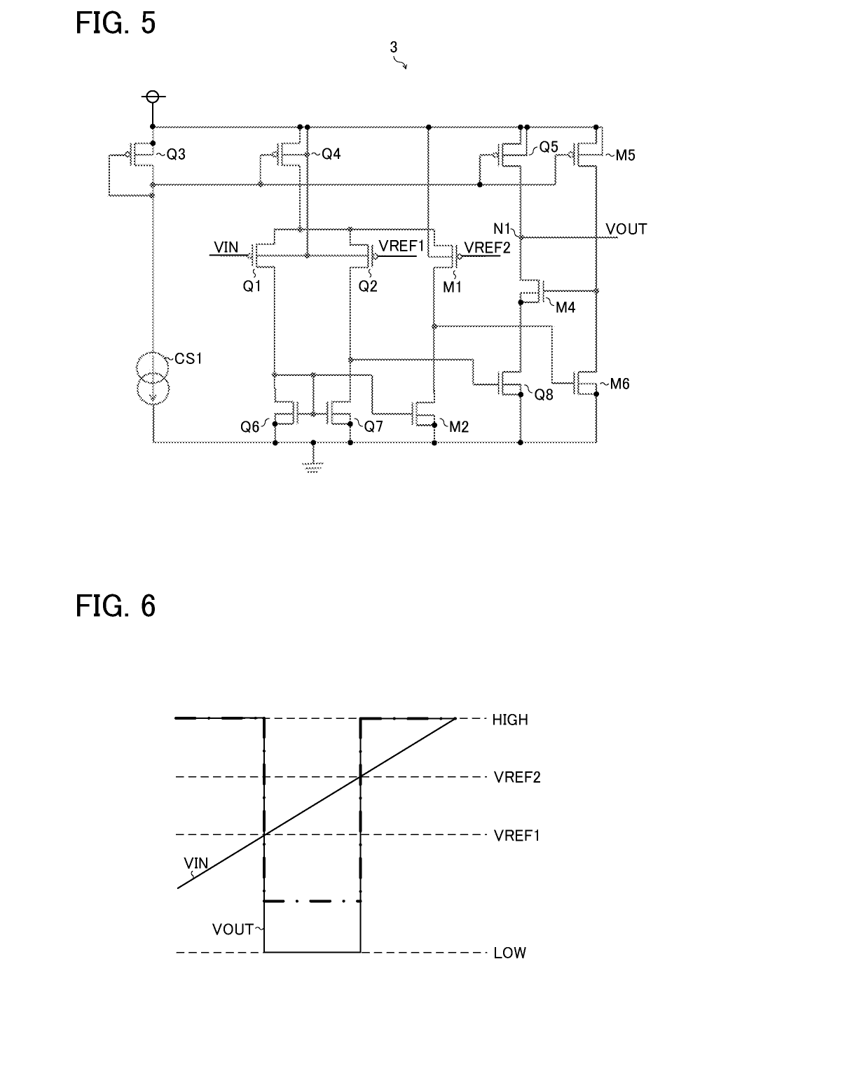

FIG. 5 is a diagram showing the configuration of a power monitoring circuit 3 according to a third embodiment. The power monitoring circuit 3 results from, as compared with the power monitoring circuit 1, removing the PMOS transistor M3 and instead adding an NMOS transistor M4, a PMOS transistor M5, and an NMOS transistor M6.

The source and back gate of the NMOS transistor M4 are connected to the drain of the NMOS transistor Q8. The drain of the NMOS transistor M4 is connected to the drain of the PMOS transistor Q5. From the connection node N1 between the drain of the PMOS transistor Q5 and the drain of the NMOS transistor M4, an output voltage VOUT is output.

The gate of the NMOS transistor M4 is connected to the drain of the PMOS transistor M5 and to the drain of the NMOS transistor M6.

The gate of the PMOS transistor M5 is connected to the gates of the PMOS transistors Q3 to Q5, to the drain of the PMOS transistor Q3, and to the first terminal of the current source CS1. A supply voltage is applied to the source and back gate of the PMOS transistor M5.

The gate of the NMOS transistor M6 is connected to the drain of the PMOS transistor M1 and to the drain of the NMOS transistor M2. A ground voltage is applied to the source and back gate of the NMOS transistor M6.

Like the power monitoring circuit 1, the power monitoring circuit 3 is configured to monitor whether the input voltage VIN as a monitoring target voltage is within a predetermined range (the range higher than the first reference voltage VREF1 but lower than the second reference voltage VREF2). As shown in FIG. 6, the power monitoring circuit 3 is configured to output, if the input voltage VIN is in the predetermined range, a low-level output voltage VOUT and, if the input voltage VIN is out of the predetermined range, a high-level output voltage VOUT.

In FIG. 6, the output voltage VOUT of the power monitoring circuit 1 is indicated by a dash-and-dot line and the output voltage VOUT of the power monitoring circuit 3 is indicated by a solid line. While the low level of the output voltage VOUT of the power monitoring circuit 1 is higher than the ground voltage by the threshold voltage of the PMOS transistor M3, the power monitoring circuit 3 can produce an output voltage VOUT of which the low level is closer to the ground voltage GND.

The power monitoring circuit 3 is configured not to require two comparators, and this helps reduce the circuit scale. The logic levels of the output voltage VOUT can be reversed by additionally providing the power monitoring circuit 3 with an inverter of which the input terminal is connected to the connection node N1 and using the voltage output from the output terminal of the inverter as the output voltage VOUT.

### Fourth Embodiment

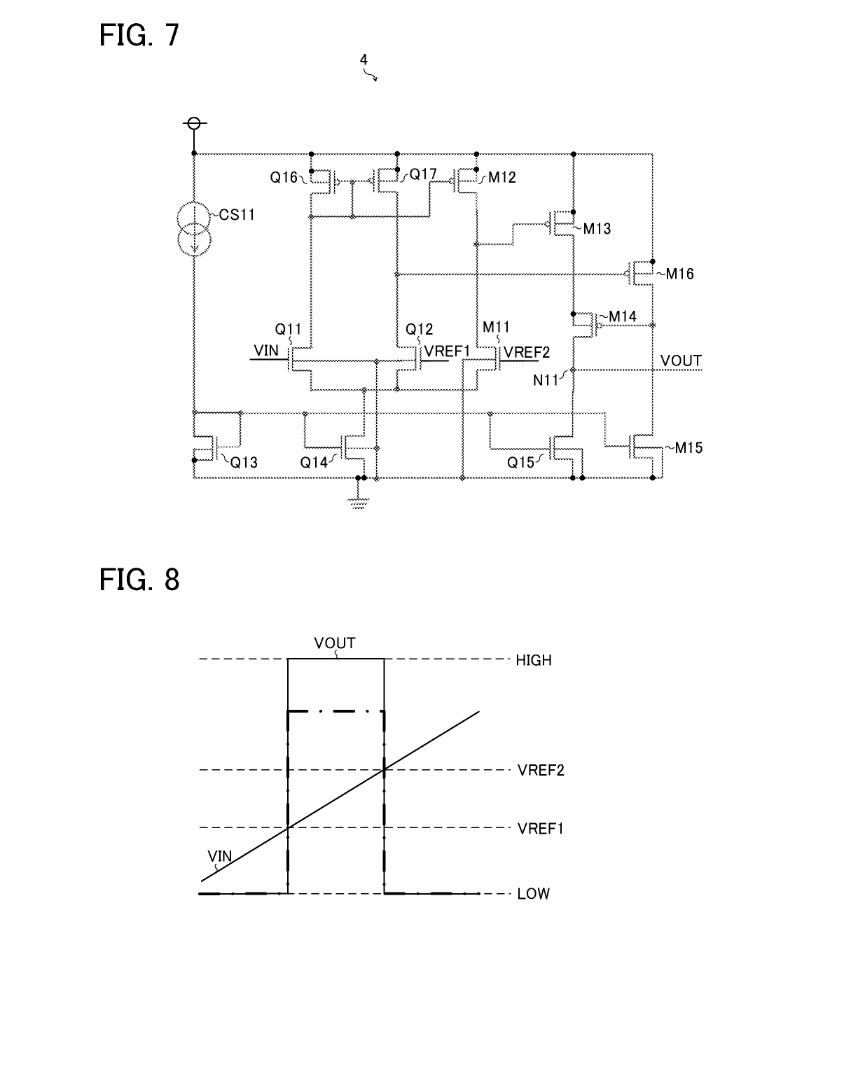

FIG. 7 is a diagram showing the configuration of a power monitoring circuit 4 according to a fourth embodiment. The power monitoring circuit 4 results from, as compared with the power monitoring circuit 2, removing the NMOS transistor Q18 and instead adding a PMOS transistor M14, an NMOS transistor M15, and a PMOS transistor M16.

The source and back gate of the PMOS transistor M14 are connected to the drain of the PMOS transistor M13. The drain of the PMOS transistor M14 is connected to the drain of the NMOS transistor Q15. From the connection node N1 between the drain of the NMOS transistor Q15 and the drain of the PMOS transistor M14, an output voltage VOUT is output.

The gate of the PMOS transistor M14 is connected to the drain of the NMOS transistor M15 and to the drain of the PMOS transistor M16.

The gate of the NMOS transistor M15 is connected to the gates of the NMOS transistors Q13 to Q15, to the drain of the NMOS transistor Q13, and to the first terminal of the current source CS11. A ground voltage is applied to the source and back gate of the NMOS transistor M15.

The gate of the PMOS transistor M16 is connected to the drain of the NMOS transistor 12 and to the drain of the PMOS transistor Q17. A supply voltage is applied to the source and back gate of the PMOS transistor M16.

Like the power monitoring circuit 2, the power monitoring circuit 4 is configured to monitor whether the input voltage VIN as a monitoring target voltage is within a predetermined range (the range higher than the first reference voltage VREF1 but lower than the second reference voltage VREF2). As shown in FIG. 8, the power monitoring circuit 4 is configured to output, if the input voltage VIN is in the predetermined range, a high-level output voltage VOUT and, if the input voltage VIN is out of the predetermined range, a low-level output voltage VOUT.

In FIG. 8, the output voltage VOUT of the power monitoring circuit 2 is indicated by a dash-and-dot line and the output voltage VOUT of the power monitoring circuit 4 is indicated by a solid line. While the high level of the output voltage VOUT of the power monitoring circuit 2 is lower than the supply voltage by the threshold voltage of the NMOS transistor Q18, the power monitoring circuit 4 can produce an output voltage VOUT of which the high level is closer to the supply voltage.

The power monitoring circuit 4 is configured not to require two comparators, and this helps reduce the circuit scale. The logic levels of the output voltage VOUT can be reversed by additionally providing the power monitoring circuit 4 with an inverter of which the input terminal is connected to the connection node N11 and using the voltage output from the output terminal of the inverter as the output voltage VOUT.

### Fifth Embodiment

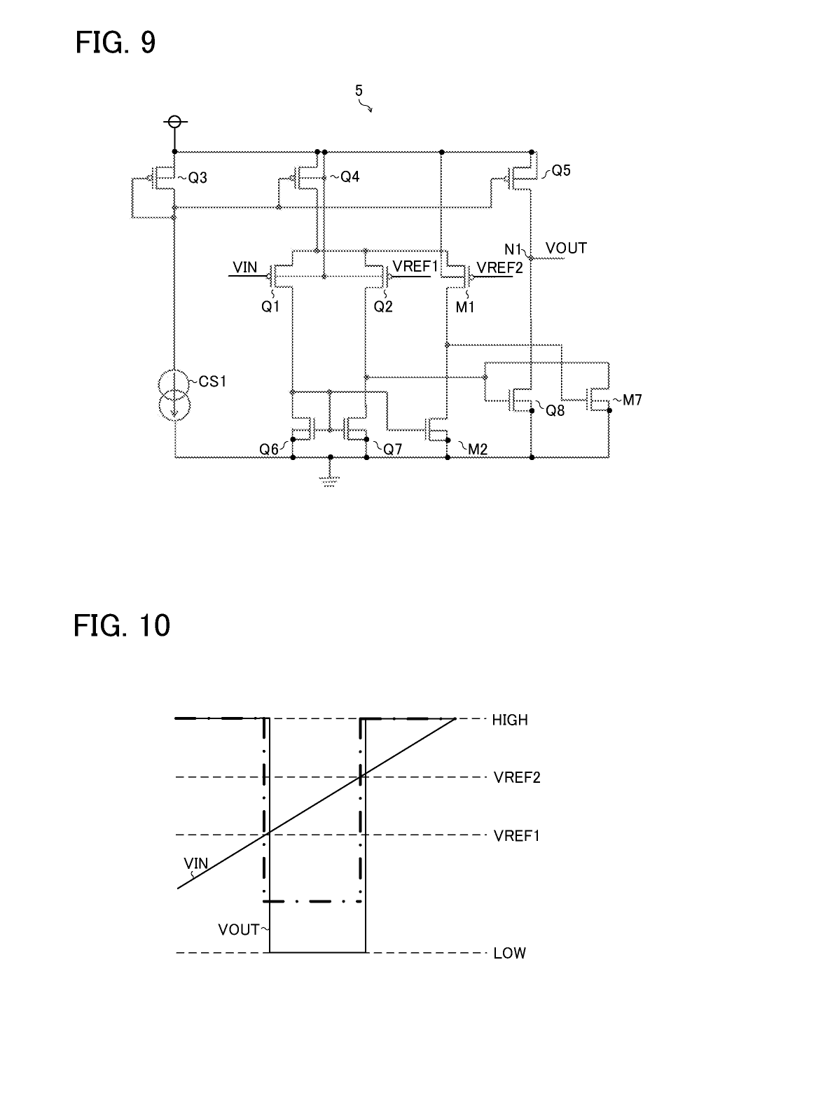

FIG. 9 is a diagram showing the configuration of a power monitoring circuit 5 according to a fifth embodiment. The power monitoring circuit 5 results from, as compared with the power monitoring circuit 1, removing the PMOS transistor M3 and instead adding an NMOS transistor M7.

The drain of the NMOS transistor Q8 is connected to the drain of the PMOS transistor Q5. The connection node N1 between the drain of the NMOS transistor Q8 and the drain of the PMOS transistor Q5, an output voltage VOUT is output.

The drain of the NMOS transistor M7 is connected to the gate of the NMOS transistor Q8, to the drain of the PMOS transistor Q2, and to the drain of the NMOS transistor Q7.

The gate of the NMOS transistor M7 is connected to the drain of the PMOS transistor M1 and to the drain of the NMOS transistor M2.

A ground voltage is applied to the source and back gate of the NMOS transistor M7.

If the input voltage VIN is lower than the first reference voltage VREF1, the drain current of the PMOS transistor Q2 and the drain current of the PMOS transistor M1 are each lower than the drain current of the PMOS transistor Q1. Thus, the gate voltage of the NMOS transistor Q8 is at low level, so that the NMOS transistor Q8 is in off state, and the gate voltage of the NMOS transistor M7 is at low level, so that the NMOS transistor M7 is in off state. As a result, the output voltage VOUT is at high level.

If the input voltage VIN is higher than the first reference voltage VREF1 but lower than the second reference voltage VREF2, the drain current of the PMOS transistor Q1 and the drain current of the PMOS transistor Q2 are each higher than the drain current of the PMOS transistor M1. Thus, the gate voltage of the NMOS transistor Q8 is at high level, so that the NMOS transistor Q8 is in on state, and the gate voltage of the NMOS transistor M7 is at low level, so that the NMOS transistor M7 is in off state. As a result, the output voltage VOUT is at low level.

If the input voltage VIN is higher than the second reference voltage VREF2, the drain current of the PMOS transistor M1 is higher than the drain current of the PMOS transistor Q1. Thus, the gate voltage of the NMOS transistor M7 is at high level, so that the NMOS transistor M7 is in on state. With the NMOS transistor M7 in on state, the gate voltage of the NMOS transistor Q8 is at low level, so that the NMOS transistor Q8 is in off state. As a result, the output voltage VOUT is at high level.

As will be understood from the operation described above, the NMOS transistor Q8 is configured to switch between on and off according to the drain current of the PMOS transistor M1 and the drain current of the PMOS transistor Q2.

Like the power monitoring circuit 1, the power monitoring circuit 5 is configured to monitor whether the input voltage VIN as a monitoring target voltage is within a predetermined range (the range higher than the first reference voltage VREF1 but lower than the second reference voltage VREF2). As shown in FIG. 10, the power monitoring circuit 5 is configured to output, if the input voltage VIN is in the predetermined range, a low-level output voltage VOUT and, if the input voltage VIN is out of the predetermined range, a high-level output voltage VOUT.

In FIG. 10, the output voltage VOUT of the power monitoring circuit 1 is indicated by a dash-and-dot line and the output voltage VOUT of the power monitoring circuit 5 is indicated by a solid line. While the low level of the output voltage VOUT of the power monitoring circuit 1 is higher than the ground voltage by the threshold voltage of the PMOS transistor M3, the power monitoring circuit 5 can produce an output voltage VOUT of which the low level is closer to the ground voltage GND, though with the drawbacks of tending to have a large offset and not permitting a large difference between the first and second reference voltages VREF1 and VREF2.

The power monitoring circuit 5 is configured not to require two comparators, and this helps reduce the circuit scale. The logic levels of the output voltage VOUT can be reversed by additionally providing the power monitoring circuit 5 with an inverter of which the input terminal is connected to the connection node N1 and using the voltage output from the output terminal of the inverter as the output voltage VOUT.

### Sixth Embodiment

FIG. 11 is a diagram showing the configuration of a power monitoring circuit 6 according to a sixth embodiment. The power monitoring circuit 6 results from, as compared with the power monitoring circuit 2, removing the NMOS transistor Q18 and instead adding a PMOS transistor M17.

The drain of the PMOS transistor M13 is connected to the drain of the NMOS transistor Q15. From the connection node N11 between the drain of the PMOS transistor M13 and the drain of the NMOS transistor Q15, an output voltage VOUT is output.

The drain of the PMOS transistor M17 is connected to the gate of the PMOS transistor M13, to the drain of the PMOS transistor M12, and to the drain of the NMOS transistor M11.

The gate of the PMOS transistor M17 is connected to the drain of the PMOS transistor Q17 and to the drain of the NMOS transistor Q12.

A supply voltage is applied to the source and back gate of the PMOS transistor M17.

If the input voltage VIN is lower than the first reference voltage VREF1, the drain current of the NMOS transistor Q12 is higher than the drain current of the NMOS transistor Q11. Thus, the gate voltage of the PMOS transistor M17 is at low level, so that the PMOS transistor M17 is in on state. With the PMOS transistor M17 in on state, the gate voltage of the PMOS transistor M13 is at high level, so that the PMOS transistor M13 is in off state. As a result, the output voltage VOUT is at low level.

If the input voltage VIN is higher than the first reference voltage VREF1 but lower than the second reference voltage VREF2, the drain current of the NMOS transistor Q11 and the drain current of the NMOS transistor Q12 are each lower than the drain current of the NMOS transistor M11. Thus, the gate voltage of the PMOS transistor M17 is at high level, so that the PMOS transistor M17 is in off state, and the gate voltage of the PMOS transistor M13 is at low level, so that the PMOS transistor M13 is in on state. As a result the output voltage VOUT is at high level.

If the input voltage VIN is higher than the second reference voltage VREF2, the drain current of the NMOS transistor Q12 and the drain current of the NMOS transistor M11 are each lower than the drain current of the NMOS transistor Q11. Thus, the gate voltage of the PMOS transistor M17 is at high level, so that the PMOS transistor M17 is in off state, and the gate voltage of the PMOS transistor M13 is at high level, so that PMOS transistor M13 is in off state. As a result, the output voltage VOUT is at low level.

As will be understood from the operation described above, the PMOS transistor M13 is configured to switch between on and off according to the drain current of the NMOS transistor M11 and the drain current of the NMOS transistor Q12.

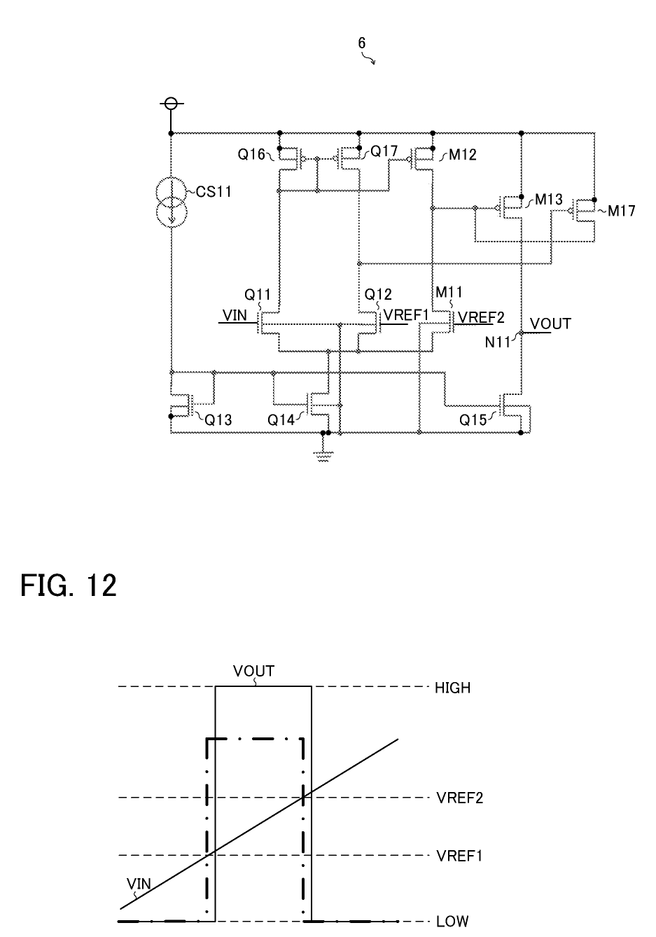

Like the power monitoring circuit 2, the power monitoring circuit 6 is configured to monitor whether the input voltage VIN as a monitoring target voltage is within a predetermined range (the range higher than the first reference voltage VREF1 but lower than the second reference voltage VREF2). As shown in FIG. 12, the power monitoring circuit 6 is configured to output, if the input voltage VIN is in the predetermined range, a high-level output voltage VOUT and, if the input voltage VIN is out of the predetermined range, a low-level output voltage VOUT.

In FIG. 12, the output voltage VOUT of the power monitoring circuit 2 is indicated by a dash-and-dot line and the output voltage VOUT of the power monitoring circuit 6 is indicated by a solid line. While the high level of the output voltage VOUT of the power monitoring circuit 2 is lower than the supply voltage by the threshold voltage of the NMOS transistor Q18, the power monitoring circuit 6 can produce an output voltage VOUT of which the high level is closer to the supply voltage, though with the drawbacks of tending to have a large offset and not permitting a large difference between the first and second reference voltages VREF1 and VREF2.

The power monitoring circuit 6 is configured not to require two comparators, and this helps reduce the circuit scale. The logic levels of the output voltage VOUT can be reversed by additionally providing the power monitoring circuit 6 with an inverter of which the input terminal is connected to the connection node N11 and using the voltage output from the output terminal of the inverter as the output voltage VOUT.

### Seventh Embodiment

FIG. 13 is a diagram showing the configuration of a power monitoring circuit 7 according to a seventh embodiment. The power monitoring circuit 7 results from, as compared with the power monitoring circuit 5, adding an NMOS transistor M8, a PMOS transistor M9, and an inverter INV1 and connecting the drain of the NMOS transistor M7 not to the gate of the NMOS transistor Q8, the drain of the PMOS transistor Q2, and the drain of the NMOS transistor Q7 but to the drain of the PMOS transistor M9 and to the input terminal of the inverter INV1.

The drain of the NMOS transistor M8 is connected to the gate of the NMOS transistor Q8, to the drain of the PMOS transistor Q2, and to the drain of the NMOS transistor Q7. The gate of the NMOS transistor M8 is connected to the output terminal of the inverter INV1. A ground voltage is applied to the source and back gate of the NMOS transistor M8.

The gate of the PMOS transistor M9 is connected to the gates of the PMOS transistors Q3 to Q5, to the drain of the PMOS transistor Q3, and to the first terminal of the current source CS1. A supply voltage is applied to the source and back gate of the PMOS transistor M9.

If the input voltage VIN is lower than the first reference voltage VREF1, the drain current of the PMOS transistor M1 is lower than the drain current of the PMOS transistor Q1. Thus, the gate voltage of the NMOS transistor M7 is at low level, so that the NMOS transistor M7 is in off state. With the NMOS transistor M7 in off state, the drain voltage of the NMOS transistor M7 is at high level, which is logically inverted by the inverter INV1 to keep the gate voltage of the NMOS transistor M8 at low level, so that the NMOS transistor M8 is in off state. On the other hand, the drain current of the PMOS transistor Q2 is lower than the drain current of the PMOS transistor Q1. Thus, the gate voltage of the NMOS transistor Q8 is at low level, so that the NMOS transistor Q8 is in off state. As a result, the output voltage VOUT is at high level.

If the input voltage VIN is higher than the first reference voltage VREF1 but lower than the second reference voltage VREF2, the drain current of the PMOS transistor Q1 and the drain current of the PMOS transistor Q2 are each higher than the drain current of the PMOS transistor M1. Thus, the gate voltage of the NMOS transistor M7 is at low level, so that the NMOS transistor M7 is in off state. With the NMOS transistor M7 in off state, the drain voltage of the NMOS transistor M7 is at high level, which is logically inverted by the inverter INV1 to keep the gate voltage of the NMOS transistor M8 at low level, so that the NMOS transistor M8 is in off state. The gate voltage of the NMOS transistor Q8 is at high level, so that the NMOS transistor Q8 is in on state. As a result, the output voltage VOUT is at low level.

If the input voltage VIN is higher than the second reference voltage VREF2, the drain current of the PMOS transistor M1 is higher than the drain current of the PMOS transistor Q1. Thus, the gate voltage of the NMOS transistor M7 is at high level, so that the NMOS transistor M7 is in on state. With the NMOS transistor M7 in on state, the drain voltage of the NMOS transistor M7 is at low level, which is logically inverted by the inverter INV1 to keep the gate voltage of the NMOS transistor M8 at high level, so that the NMOS transistor M8 is in on state. With the NMOS transistor M8 in on state, the gate voltage of the NMOS transistor Q8 is at low level, so that the NMOS transistor Q8 is in off state. As a result, the output voltage VOUT is at high level.

As will be understood from the operation described above, the NMOS transistor Q8 is configured to switch between on and off according to the drain current of the PMOS transistor M1 and the drain current of the PMOS transistor Q2.

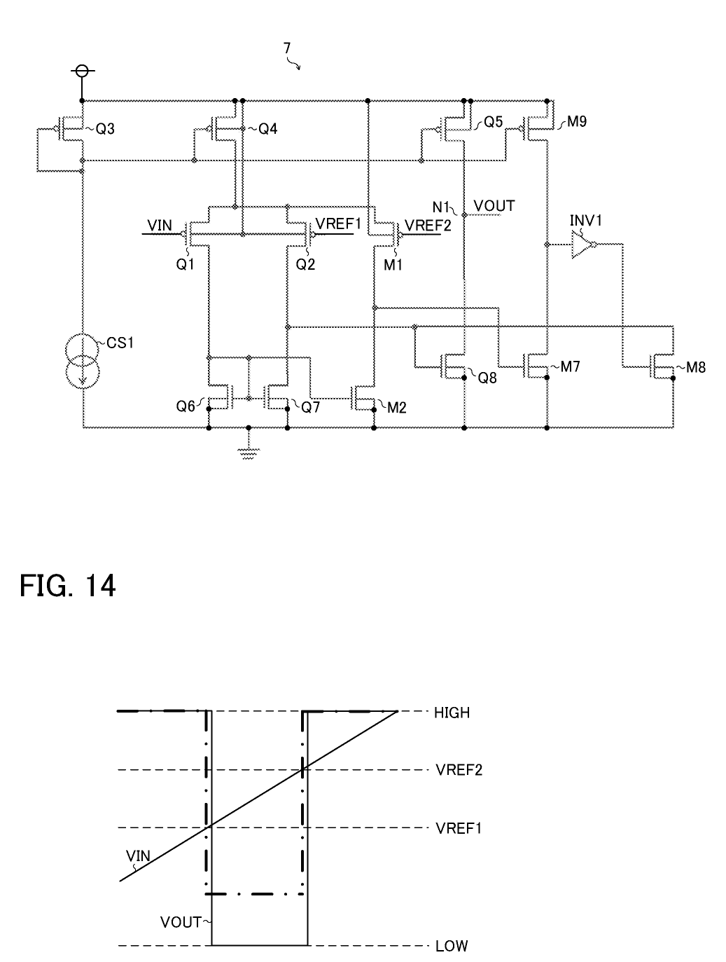

Like the power monitoring circuit 1, the power monitoring circuit 7 is configured to monitor whether the input voltage VIN as a monitoring target voltage is within a predetermined range (the range higher than the first reference voltage VREF1 but lower than the second reference voltage VREF2). As shown in FIG. 14, the power monitoring circuit 7 is configured to output, if the input voltage VIN is in the predetermined range, a low-level output voltage VOUT and, if the input voltage VIN is out of the predetermined range, a high-level output voltage VOUT.

In FIG. 14, the output voltage VOUT of the power monitoring circuit 1 is indicated by a dash-and-dot line and the output voltage VOUT of the power monitoring circuit 7 is indicated by a solid line. While the low level of the output voltage VOUT of the power monitoring circuit 1 is higher than the ground voltage by the threshold voltage of the PMOS transistor M3, the power monitoring circuit 7 can produce an output voltage VOUT of which the low level is closer to the ground voltage GND, though with the drawbacks of tending to have a large offset and not allowing a large difference between the first and second reference voltages VREF1 and VREF2.

The power monitoring circuit 7 is configured not to require two comparators, and this helps reduce the circuit scale. The logic levels of the output voltage VOUT can be reversed by additionally providing the power monitoring circuit 7 with an inverter of which the input terminal is connected to the connection node N1 and using the voltage output from the output terminal of the inverter as the output voltage VOUT.

### Eighth Configuration

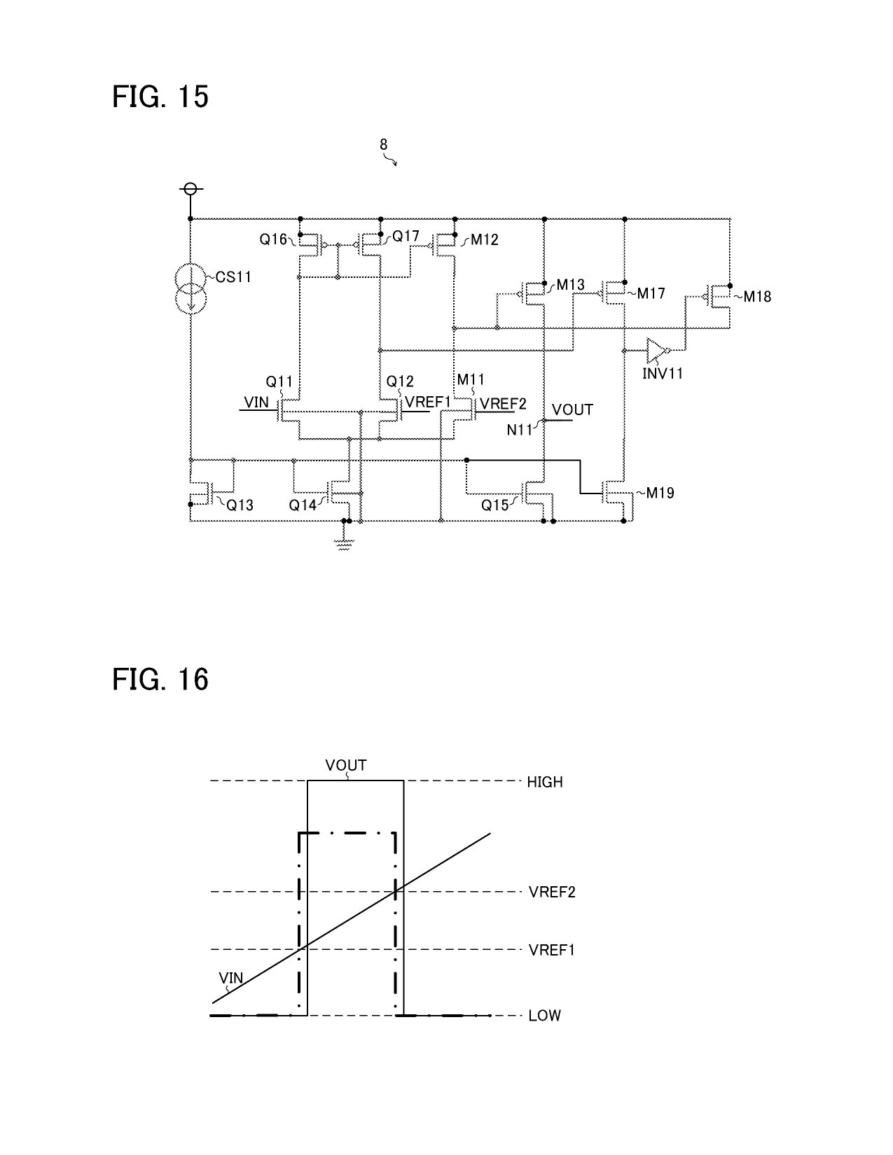

FIG. 15 is a diagram showing the configuration of a power monitoring circuit 8 according to an eighth embodiment. The power monitoring circuit 8 results from, as compared with the power monitoring circuit 6, adding a PMOS transistor M18, an NMOS transistor M19, and an inverter INV11 and connecting the drain of the PMOS transistor M17 not to the gate of the PMOS transistor M13, the drain of the PMOS transistor M12, and the drain of the NMOS transistor M11 but to the drain of the NMOS transistor M19 and to the input terminal of the inverter INV11.

The drain of the PMOS transistor M18 is connected to the gate of the PMOS transistor M13, to the drain of the NMOS transistor M11, and to the drain of the PMOS transistor M12. The gate of the PMOS transistor M18 is connected to the output terminal of the inverter INV11. A supply voltage is applied to source and back gate of the PMOS transistor M18.

The gate of the NMOS transistor M19 is connected to the gates of the NMOS transistors Q13 to Q15, to the drain of the NMOS transistor Q13, and to the first terminal of the current source CS11. A ground voltage is applied to the source and back gate of the NMOS transistor M19.

If the input voltage VIN is lower than the first reference voltage VREF1, the drain current of the NMOS transistor Q12 is higher than the drain current of the NMOS transistor Q11. Thus, the gate voltage of the PMOS transistor M17 is at low level, so that the PMOS transistor M17 is in on state. With the PMOS transistor M17 in on state, the drain voltage of the PMOS transistor M17 is at high level, which is logically inverted by the inverter INV11 to keep the gate voltage of the PMOS transistor M18 at low level, so that the PMOS transistor M18 is in on state. With the PMOS transistor M18 in on state, the gate voltage of the PMOS transistor M13 is at high level, so that the PMOS transistor M13 is in off state. As a result, the output voltage VOUT is at low level.

If the input voltage VIN is higher than the first reference voltage VREF1 but lower than the second reference voltage VREF2, the drain current of the NMOS transistor Q11 and the drain current of the NMOS transistor Q12 are each lower than the drain current of the NMOS transistor M11. Thus, the gate voltage of the PMOS transistor M17 is at high level, so that the PMOS transistor M17 is in off state. With the PMOS transistor M17 in off state, the drain voltage of the PMOS transistor M17 is at low level, which is logically inverted by the inverter INV11 to keep the gate voltage of the PMOS transistor M18 at high level, so that the PMOS transistor M18 is in off state. The gate voltage of the PMOS transistor M13 is at low level, so that the PMOS transistor M13 is in on state. As a result, the output voltage VOUT is at high level.

If the input voltage VIN is higher than the second reference voltage VREF2, the drain current of the NMOS transistor Q12 is lower than the drain current of the NMOS transistor Q11. Thus, the gate voltage of the PMOS transistor M17 is at high level, so that the PMOS transistor M17 is in off state. With the PMOS transistor M17 in off state, the drain voltage of the PMOS transistor M17 is at low level, which is logically inverted by the inverter INV11 to keep the gate voltage of the PMOS transistor M18 at high level, so that the PMOS transistor M18 is in off state. On the other hand, the drain current of the NMOS transistor M11 is lower than the drain current of the NMOS transistor Q11. Thus, the gate voltage of the PMOS transistor M13 is at high level, so that the PMOS transistor M13 is in off state. As a result, the output voltage VOUT is at low level.

As will be understood from the operation described above, the PMOS transistor M13 is configured to switch between on and off according to the drain current of the NMOS transistor M11 and the drain current of the NMOS transistor Q12.

Like the power monitoring circuit 2, the power monitoring circuit 8 is configured to monitor whether the input voltage VIN as a monitoring target voltage is within a predetermined range (the range higher than the first reference voltage VREF1 but lower than the second reference voltage VREF2). As shown in FIG. 16, the power monitoring circuit 8 is configured to output, if the input voltage VIN is in the predetermined range, a high-level output voltage VOUT and, if the input voltage VIN is out of the predetermined range, a low-level output voltage VOUT.

In FIG. 16, the output voltage VOUT of the power monitoring circuit 2 is indicated by a dash-and-dot line and the output voltage VOUT of the power monitoring circuit 8 is indicated by a solid line. While the high level of the output voltage VOUT of the power monitoring circuit 2 is lower than the supply voltage by the threshold voltage of the NMOS transistor Q18, the power monitoring circuit 8 can produce an output voltage VOUT of which the high level is closer to the supply voltage, though with the drawbacks of tending to have a large offset and not permitting a large difference between the first and second reference voltages VREF1 and VREF2.

The power monitoring circuit 8 is configured not to require two comparators, and this helps reduce the circuit scale. The logic levels of the output voltage VOUT can be reversed by additionally providing the power monitoring circuit 8 with an inverter of which the input terminal is connected to the connection node N11 and using the voltage output from the output terminal of the inverter as the output voltage VOUT.

### Application Example

Any of the power monitoring circuits 1 to 8 described above can be incorporated, for example, in a power supply circuit 10 as shown in FIG. 17. The power supply circuit 10 includes a DC/DC converter 11 and an output voltage monitoring circuit 12. The DC/DC converter 11 converts an input voltage Vi into an output voltage Vo. The DC/DC converter 11 can be a switching regulator or a linear regulator. The output voltage monitoring circuit 12 is configured to monitor whether the output voltage Vo as a monitoring target voltage is in a predetermined range (a range higher than a first reference voltage VREF1 but lower than a second reference voltage VREF2). One of the power monitoring circuits 1 to 8 described above is used as the output voltage monitoring circuit 12. There is no particular limitation on the use of the output voltage VOUT output from the output voltage monitoring circuit 12. For example, a configuration is possible where, if the output voltage Vo is out of the predetermined range, the DC/DC converter 11 stops operating according to the output voltage VOUT. In the power supply circuit 10, one of the power monitoring circuits 1 to 8 described above monitors the output voltage Vo; instead, one of the power monitoring circuits 1 to 8 described above can monitor any voltage other than output voltage Vo.

### Notes

The embodiments described above should be considered to be in every aspect illustrative and not restrictive. The technical scope of the present disclosure is defined not by the description of embodiments given above but by the appended claims and should be understood to encompass any modifications within a scope equivalent in significance to those claims.

### Overview

To follow is an overview of the present disclosure, of which examples of specific configurations have been described above by way of embodiments.

According to one aspect of the present disclosure, a voltage monitoring circuit (1-8) includes: a first field-effect transistor (Q2, Q12) configured to be fed at its gate with a first reference voltage (VREF1); a second field-effect transistor (M1, M11) configured to be fed at its gate with a second reference voltage (VREF2) higher than the first reference voltage; a third field-effect transistor (Q1, Q11) configured to be fed at its gate with a monitoring target voltage (VIN) and to have its source connected to the source of the first field-effect transistor and to the source of the second field-effect transistor; a fourth field-effect transistor (M3, M13, M6, M7) configured to be turned on and off according to the drain current of the second field-effect transistor; and a fifth field-effect transistor (Q8, Q18, M16, M17) configured to be turned on and off according to the drain current of the first field-effect transistor. (A first configuration.)

The voltage monitoring circuit of the first configuration described above is configured not to require two comparators. This contributes to a reduced circuit scale.

In the voltage monitoring circuit of the first configuration described above, the forth and fifth field-effect transistors can be configured to be connected in series. (A second configuration.)

In the voltage monitoring circuit of the second configuration described above, the fourth field-effect transistor (M3, M13) can be a P-channel field-effect transistor and the fifth field-effect transistor (Q8, Q18) can an N-channel field-effect transistor. (A third configuration.)

The voltage monitoring circuit of the first configuration described above can further include: a sixth field-effect transistor (M4) configured to have its gate connected to the drain of the fourth field-effect transistor (M6) and to be connected in series with the fifth field-effect transistor (Q8). The first to third field-effect transistors can be P-channel field-effect transistors, and the fourth to sixth field-effect transistors can be N-channel field-effect transistors. (A fourth configuration.)

The voltage monitoring circuit of the first configuration described above can further include: a sixth field-effect transistor (M14) configured to have its gate connected to a drain of the fifth field-effect transistor (M16) and to be connected in series with the fourth field-effect transistor (M13). The first to third field-effect transistors can be N-channel field-effect transistors, and the fourth to sixth field-effect transistors can be P-channel field-effect transistors. (A fifth configuration.)

In the voltage monitoring circuit of the first configuration described above, the first to third field-effect transistors can be P-channel field-effect transistors, and the fourth to fifth field-effect transistors can be N-channel field-effect transistors. The fifth field-effect transistor (Q8) can be configured to have its gate connected to the drain of the fourth field-effect transistor (M7). The fifth field-effect transistor can be configured to be turned on and off according to the drain current of the first field-effect transistor and the drain current of the second field-effect transistor. (A sixth configuration.)

In the voltage monitoring circuit of the first configuration described above, the first to third field-effect transistors can be N-channel field-effect transistors, and the fourth to fifth field-effect transistors can be P-channel field-effect transistors. The fourth field-effect transistor (M13) is configured to have its gate connected to the drain of the fifth field-effect transistor (M17). The fourth field-effect transistor is configured to be turned on and off according to the drain current of the first field-effect transistor and the drain current of the second field-effect transistor. (A seventh configuration.)

The voltage monitoring circuit of the first configuration described above can further include: a sixth field-effect transistor (M8) configured to be fed at its gate with the logical inversion of the drain voltage of the fourth field-effect transistor (M7) and to have its drain connected to the gate of the fifth field-effect transistor (Q8). The first to third field-effect transistors can be P-channel field-effect transistors, and the fourth to sixth field-effect transistors can be N-channel field-effect transistors. The fifth field-effect transistor can be configured to be turned on and off according to the drain current of the first field-effect transistor and the drain current of the second field-effect transistor. (An eighth configuration.)

The voltage monitoring circuit of the first configuration described above can further include: a sixth field-effect transistor (M18) configured to be fed at its gate with the logical inversion of the drain voltage of the fifth field-effect transistor (M17) and to have its drain connected to the gate of the fourth field-effect transistor (M13). The first to third field-effect transistors can be N-channel field-effect transistors, and the fourth to sixth field-effect transistors can be P-channel field-effect transistors. The fourth field-effect transistor can be configured to be turned on and off according to the drain current of the first field-effect transistor and the drain current of the second field-effect transistor. (A ninth configuration.)

According to another aspect of the present disclosure, a power supply circuit (10) includes the voltage monitoring circuit of any of the first to ninth configurations described above. (A tenth configuration.)

What is claimed is:

1. A voltage monitoring circuit comprising:
a first field-effect transistor configured to be fed at a gate with a first reference voltage;
a second field-effect transistor configured to be fed at a gate with a second reference voltage higher than the first reference voltage;
a third field-effect transistor configured to be fed at a gate with a monitoring target voltage and to have a source connected to a source of the first field-effect transistor and to a source of the second field-effect transistor;
a fourth field-effect transistor configured to be turned on and off according to a drain current of the second field-effect transistor; and
a fifth field-effect transistor configured to be turned on and off according to a drain current of the first field-effect transistor.

2. The voltage monitoring circuit according to claim 1, wherein
the forth and fifth field-effect transistors are configured to be connected in series.

3. The voltage monitoring circuit according to claim 2, wherein
the fourth field-effect transistor is a P-channel field-effect transistor and the fifth field-effect transistor is an N-channel field-effect transistor.

4. The voltage monitoring circuit according to claim 1, further comprising:
a sixth field-effect transistor configured to have a gate connected to a drain of the fourth field-effect transistor and to be connected in series with the fifth field-effect transistor,
the first to third field-effect transistors are P-channel field-effect transistors, and
the fourth to sixth field-effect transistors are N-channel field-effect transistors.

5. The voltage monitoring circuit according to claim 1, further comprising:
a sixth field-effect transistor configured to have a gate connected to a drain of the fifth field-effect transistor and to be connected in series with the fourth field-effect transistor,
the first to third field-effect transistors are N-channel field-effect transistors, and
the fourth to sixth field-effect transistors are P-channel field-effect transistors.

6. The voltage monitoring circuit according to claim 1, wherein
the first to third field-effect transistors are P-channel field-effect transistors,
the fourth to fifth field-effect transistors are N-channel field-effect transistors,
the fifth field-effect transistor is configured to have a gate connected to a drain of the fourth field-effect transistor, and
the fifth field-effect transistor is configured to be turned on and off according to a drain current of the first field-effect transistor and a drain current of the second field-effect transistor.

7. The voltage monitoring circuit according to claim 1, wherein
the first to third field-effect transistors are N-channel field-effect transistors,
the fourth to fifth field-effect transistors are P-channel field-effect transistors,
the fourth field-effect transistor is configured to have a gate connected to a drain of the fifth field-effect transistor, and
the fourth field-effect transistor is configured to be turned on and off according to a drain current of the first field-effect transistor and a drain current of the second field-effect transistor.

8. The voltage monitoring circuit according to claim 1, further comprising:
a sixth field-effect transistor configured to be fed at a gate with a logical inversion of a drain voltage of the fourth field-effect transistor and to have a drain connected to a gate of the fifth field-effect transistor,
the first to third field-effect transistors are P-channel field-effect transistors,
the fourth to sixth field-effect transistors are N-channel field-effect transistors,
the fifth field-effect transistor is configured to be turned on and off according to a drain current of the first field-effect transistor and a drain current of the second field-effect transistor.

9. The voltage monitoring circuit according to claim 1, further comprising:
a sixth field-effect transistor configured to be fed at a gate with a logical inversion of a drain voltage of the fifth field-effect transistor and to have a drain connected to a gate of the fourth field-effect transistor,
the first to third field-effect transistors are N-channel field-effect transistors,
the fourth to sixth field-effect transistors are P-channel field-effect transistors,
the fourth field-effect transistor is configured to be turned on and off according to a drain current of the first field-effect transistor and a drain current of the second field-effect transistor.

10. A power supply circuit comprising the voltage monitoring circuit according to claim 1.

11. A power supply circuit comprising the voltage monitoring circuit according to claim 2.

12. A power supply circuit comprising the voltage monitoring circuit according to claim 3.

13. A power supply circuit comprising the voltage monitoring circuit according to claim 4.

14. A power supply circuit comprising the voltage monitoring circuit according to claim 5.

15. A power supply circuit comprising the voltage monitoring circuit according to claim 6.

16. A power supply circuit comprising the voltage monitoring circuit according to claim 7.

17. A power supply circuit comprising the voltage monitoring circuit according to claim 8.

18. A power supply circuit comprising the voltage monitoring circuit according to claim 9.
